(19) United States
(12) Patent Application Publication
(10) Pub. No.: US 2009/0302887 A1
(43) Pub. Date: Dec. 10, 2009

(54) APPARATUS FOR POWER CONSUMPTION REDUCTION IN PROGRAMMABLE LOGIC DEVICES AND ASSOCIATED METHODS

(76) Inventors: Tad Kwasniewski, Ottawa (CA); Rakesh H. Patel, Cupertino, CA (US)

Correspondence Address: LAW OFFICES OF MAXIMILIAN R. PETERSON, P.O. BOX 93005, AUSTIN, TX, 78709-3005, US

(21) Appl. No.: 12/236,491

(22) Filed: Sep. 23, 2008

Related U.S. Application Data
(60) Provisional application No. 61/060,366, filed on Jun. 10, 2008.

(51) Int. Cl. H03K 19/173; H03K 19/177; H03K 19/094

(52) U.S. Cl. 326/38; 326/39; 326/115; 326/83

(57) ABSTRACT

A programmable logic device (PLD) includes a driver circuit, a configuration memory, and a control circuit. The configuration memory stores driver strength information for the driver circuit. The control circuit uses the driver strength information stored in the configuration circuit to control the driver strength of the driver.

### CROSS-REFERENCE TO RELATED APPLICATIONS

This application claims priority to, and incorporates by reference, U.S. Provisional Patent Application Ser. No. 61/060,366, filed on Jun. 10, 2008, attorney docket number ALTR062P1.

### TECHNICAL FIELD

The disclosed concepts relate generally to controlling, adjusting, and optimizing the performance of programmable logic devices (PLDs) and, more particularly, to adjusting power consumption of PLDs.

### BACKGROUND

PLDs are flexible electronic devices that allow users to change or program the functionality of the device as desired. To accommodate the users' increasingly complex designs, modern PLDs include a relatively large number of transistors. As a result, power consumption, power dissipation, die temperatures and, hence, power density (power dissipation in various circuits or blocks), of PLDs has become an increasingly important issue.

### SUMMARY

In one illustrative embodiment, a programmable logic device (PLD) includes a driver circuit, a configuration memory, and a control circuit. The configuration memory stores driver strength information for the driver circuit. The control circuit uses the driver strength information stored in the configuration circuit to control the driver strength of the driver. In another exemplary embodiment, a PLD includes a driver circuit that communicates a signal, and a receiver circuit that receives the signal, and generates a received signal. The PLD also includes a control circuit that uses at least one quality criterion of the received signal to control a characteristic of the driver circuit. In yet another exemplary embodiment, a method of controlling power consumption of a PLD includes generating information about a driver circuit's current-driving capability, and storing the information about the driver circuit's current-driving capability. The method further includes using the information to control the driver circuit's current-driving capability.

### BRIEF DESCRIPTION OF THE DRAWINGS

The appended drawings illustrate only exemplary embodiments and therefore should not be considered as limiting its scope. Persons of ordinary skill in the art who have the benefit of this disclosure appreciate that the disclosed concepts lend themselves to other equally effective embodiments. In the drawings, the same numeral designators used in more than one drawing denote the same, similar, or equivalent functionality, components, or blocks.

FIG. 1 illustrates a general block diagram of a PLD according to exemplary embodiments.

FIG. 2 shows various software modules of PLD computer-aided design (CAD) software according to an illustrative embodiment.

FIG. 3 shows a conceptual, simplified block diagram of programmable logic and programmable interconnect in a PLD according to an exemplary embodiment.

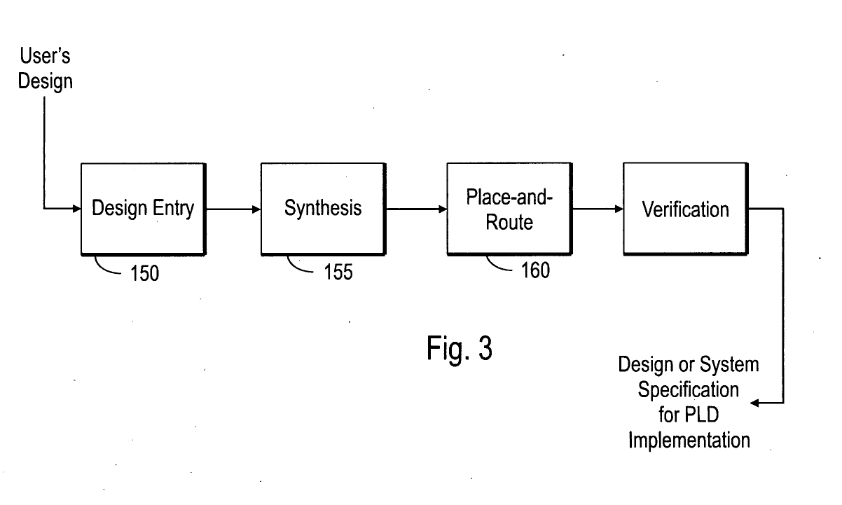

FIG. 4 depicts a conceptual block diagram of circuitry for controlling power consumption in a PLD according to an exemplary embodiment.

FIG. 5 shows a simplified schematic of a driver circuit according to an exemplary embodiment.

FIG. 6 illustrates a simplified schematic of a driver circuit according to another exemplary embodiment.

FIG. 7 depicts a simplified schematic of a driver circuit according to an additional exemplary embodiment.

FIG. 8 shows a simplified schematic of a driver circuit according to yet another exemplary embodiment.

FIG. 9 illustrates a conceptual block diagram of circuitry for controlling power consumption in a PLD according to an exemplary embodiment.

FIG. 10 depicts a conceptual block diagram of circuitry for controlling power consumption in a PLD according to another exemplary embodiment.

### DETAILED DESCRIPTION

The disclosed concepts relate to apparatus and associated methods for controlling, adjusting, and optimizing power consumption of PLDs. More specifically, the disclosed concept provide techniques for controlling the power consumption of interconnect circuitry within PLDs.

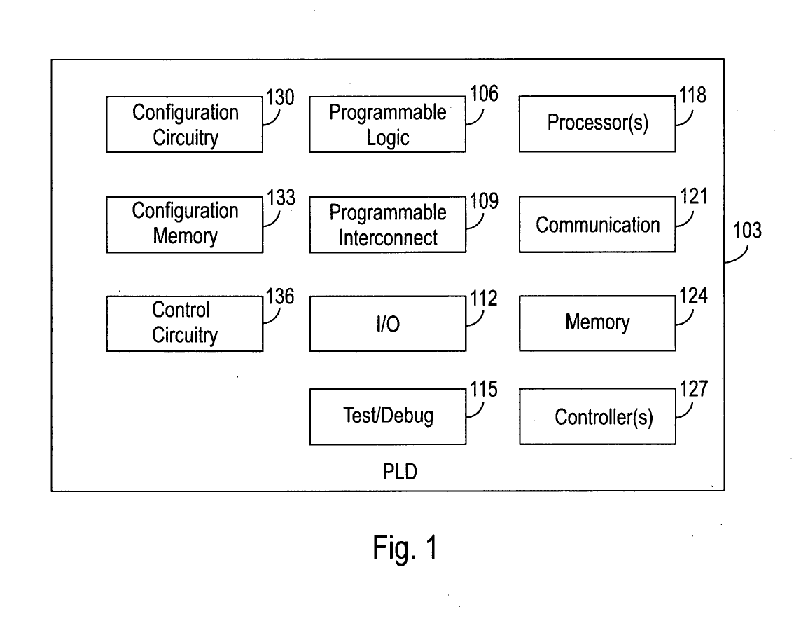

FIG. 1 shows a general block diagram of a PLD 103 according to an illustrative embodiments. PLD 103 includes configuration circuitry 130, configuration memory (CRAM) 133, control circuitry 136, programmable logic 106, programmable interconnect 109, and I/O circuitry 112. In addition, PLD 103 may include test/debug circuitry 115, one or more processors 118, one or more communication circuitry 121, one or more memories 124, one or more controllers 127, as desired.

Note that FIG. 1 shows a simplified block diagram of PLD 103. Thus, PLD 103 may include other blocks and circuitry, as persons of ordinary skill in the art understand. Examples of such circuitry include clock generation and distribution circuits, redundancy circuits, and the like. Furthermore, PLD 103 may include, analog circuitry, other digital circuitry, and/or mixed-signal circuitry, as desired. One may the design methodology and disclosed concepts to various resources, blocks, or circuits of PLD 103, as desired. Furthermore, one may apply the disclosed methodology and concepts to other PLD architectures, including any desired blocks, regions, or circuits, as persons of ordinary skill in the art who have the benefit of the description of the disclosed concepts understand.

Programmable logic 106 includes blocks of configurable or programmable logic circuitry, such as look-up tables (LUTs), product-term logic, multiplexers (MUXs), logic gates, registers, memory, and the like. Programmable interconnect 109 couples to programmable logic 106 and provides configurable interconnects (coupling mechanisms) between various blocks within programmable logic 106 and other circuitry within or outside PLD 103.

Control circuitry 136 controls various operations within PLD 103, including aspects of the techniques for controlling, adjusting, and optimizing the power consumption of PLD 103, as described below in detail. Under the supervision of control circuitry 136, PLD configuration circuitry 130 uses configuration data (which it obtains from an external source, such as a storage device, a host, etc.) to program or configure the functionality of PLD 103. Configuration data typically store information in CRAM 133. The contents of CRAM 133 determine the functionality of various blocks of PLD 103, such as programmable logic 106 and programmable interconnect 109, as persons of ordinary skill in the art who have the benefit of this disclosure understand.

I/O circuitry 112 may constitute a wide variety of I/O devices or circuits, as persons of ordinary skill in the art who have the benefit of the description of the disclosed concepts understand. I/O circuitry 112 may couple to various parts of PLD 103, for example, programmable logic 106 and programmable interconnect 109. I/O circuitry 112 provides a mechanism and circuitry for various blocks within PLD 103 to communicate with external circuitry or devices.

Test/debug circuitry 115 facilitates the testing and troubleshooting of various blocks and circuits within PLD 103. Test/debug circuitry 115 may include a variety of blocks or circuits known to persons of ordinary skill in the art who have the benefit of the description of the disclosed concepts. For example, test/debug circuitry 115 may include circuits for performing tests after PLD 103 powers up or resets, as desired. Test/debug circuitry 115 may also include coding and parity circuits, as desired.

PLD 103 may include one or more processors 118. Processor 118 may couple to other blocks and circuits within PLD 103. Processor 118 may receive data and information from circuits within or external to PLD 103 and process the information in a wide variety of ways, as persons skilled in the art with the benefit of the description of the disclosed concepts appreciate. One or more of processor(s) 118 may constitute a digital signal processor (DSP). DSPs allow performing a wide variety of signal processing tasks, such as compression, decompression, audio processing, video processing, filtering, and the like, as desired.

PLD 103 may also include one or more communication circuits 121. Communication circuit(s) 121 may facilitate data and information exchange between various circuits within PLD 103 and circuits external to PLD 103, as persons of ordinary skill in the art who have the benefit of this disclosure understand.

PLD 103 may further include one or more memories 124 and one or more controller(s) 127. Memory 124 allows the storage of various data and information (such as user-data, intermediate results, calculation results, etc.) within PLD 103. Memory 124 may have a granular or block form, as desired. Controller 127 allows interfacing to, and controlling the operation and various functions of circuitry outside the PLD. For example, controller 127 may constitute a memory controller that interfaces to and controls an external synchronous dynamic random access memory (SDRAM), as desired.

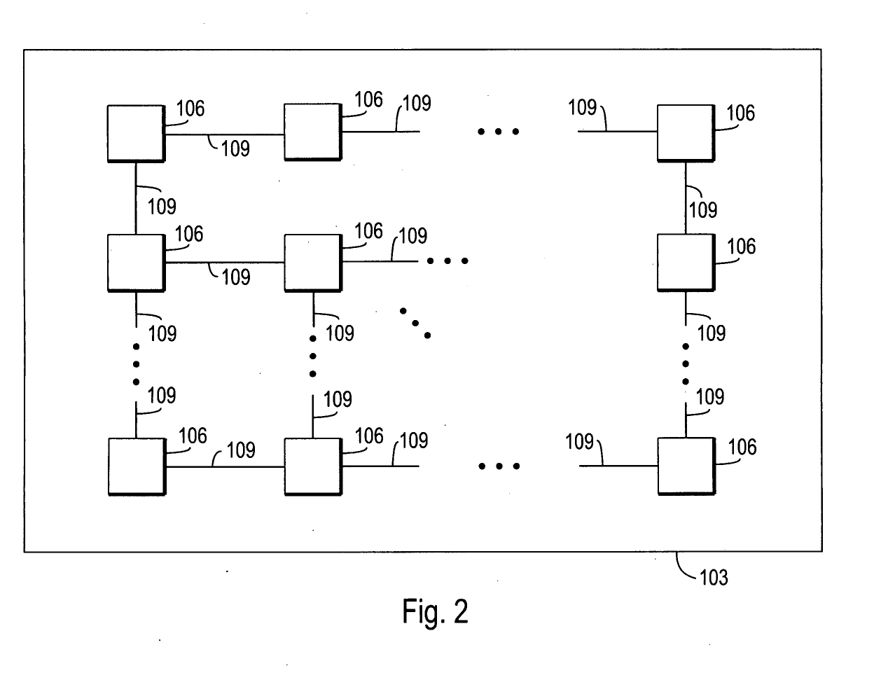

FIG. 2 shows a conceptual, simplified block diagram of programmable logic 106 and programmable interconnect 109 in a PLD according to an exemplary embodiment. PLD 103 includes programmable logic 106 arranged as a two-dimensional array. Programmable interconnect 109, arranged as horizontal interconnect and vertical interconnect, couples the blocks of programmable logic 106 to one another.

In illustrative embodiments, PLDs may have a hierarchical architecture. In other words, each block of programmable logic 106 may in turn include smaller or more granular programmable logic blocks or circuits. Furthermore, programmable interconnect 109 may have a hierarchical architecture. As persons of ordinary skill in the art who have the benefit of the description of the disclosed concepts understand, programmable interconnect 109 may include segments of interconnect circuitry that couple parts of programmable logic 106 to other circuitry within or outside PLD 103.

Programmable interconnect 109 may include interconnect circuitry that spans across an entire row or column of circuitry within PLD 103, or a subset of a row and/or column, as desired, and as persons of ordinary skill in the art who have the benefit of the description of the disclosed concepts understand. Generally speaking, the architecture of programmable interconnect 109 depends on the overall architecture of PLD 103. Regardless of the specific details and architecture of programmable interconnect 109, one may use the disclosed techniques to adjust or control the power consumption of at least a portion of programmable interconnect 109 and, hence, of PLD 103 overall.

Implementing a design in a PLD often entails using CAD software. According to one aspect of the disclosed concepts, CAD software determines information (e.g., appropriate or desired “driver strength”) about various drivers in programmable interconnect 109 in PLD 103. The CAD software may determine the information based on various factors, such as the physical location and electrical attributes of the driver, the receiver, the coupling mechanisms, and the like, as persons of ordinary skill in the art who have the benefit of the description of the disclosed concepts understand.

FIG. 2 shows various software modules that PLD computer-aided design (CAD) software according to illustrative embodiments use. The modules include design-entry module 150, synthesis module 155, place-and-route module 160, and verification module 165. The following description provides a simplified explanation of the operation of each module, followed by a description of CAD techniques to reduce or minimize power consumption in PLDs.

Design-entry module 150 allows the integration of multiple design files. The user may generate the design files by using design-entry module 150 or by using a variety of electronic design automation (EDA) or CAD tools (such as industry-standard EDA tools), as desired. The user may enter the design in a graphic format, a waveform-based format, a schematic format, in a text or binary format, or as a combination of those formats, as desired.

Synthesis module 155 accepts the output of design-entry module 150. Based on the user-provided design, synthesis module 155 generates appropriate logic circuitry that realizes the user-provided design. One or more PLDs (not shown explicitly) implement the synthesized overall design or system.

Synthesis module 155 may also generate any glue logic that allows integration and proper operation and interfacing of various modules in the user's designs. For example, synthesis module 155 provides appropriate hardware so that an output of one block properly interfaces with an input of another block. Synthesis module 155 may provide appropriate hardware so as to meet the specifications of each of the modules in the overall design or system.

Furthermore, synthesis module 155 may include algorithms and routines for optimizing the synthesized design. Through optimization, synthesis module 155 seeks to more efficiently use the resources of the one or more PLDs that implement the overall design or system. Synthesis module 155 provides its output to place-and-route module 160.

Place-and-route module 160 uses the designer's timing specifications to perform optimal logic mapping and placement. The logic mapping and placement determine the use of routing resources within the PLD(s). In other words, by use of particular programmable interconnects with the PLD(s) for certain parts of the design, place-and-route module 160 helps optimize the performance of the overall design or system. By proper use of PLD routing resources, place-and-route module 160 helps to meet the critical timing paths of the overall design or system.

Place-and-route module 160 optimizes the critical timing paths to help provides timing closure faster in a manner known to persons of ordinary skill in the art with the benefit of the description of the disclosed concepts. As a result, the overall design or system can achieve faster performance (i.e., operate at a higher clock rate or have higher throughput). Place-and-route module 160 may use information about critical paths within the design or system to adjust power consumption of parts or all of the design or system, as desired. Thus, place-and-route module 160 might provide information (by storing the information in configuration CRAM 133) about the appropriate or desired “driver strength”) for one or more drivers in PLD 103. The information becomes available to various circuitry (e.g., control circuitry 136) in PLD 103 during the user mode (i.e., the mode in which PLD 103 implements the user's desired circuit or function).

As described below, this information, along with driver circuitry that allows the control or adjustment of “driver strength” for a given driver, provides a mechanism for controlling, adjusting, or optimizing the power consumption of that driver. One may use this technique for as few or as many drivers as desired, as persons of ordinary skill in the art who have the benefit of the description of the disclosed concepts understand.

Verification module 165 performs simulation and verification of the design. The simulation and verification seek in part to verify that the design complies with the user's prescribed specifications. The simulation and verification also aim at detecting and correcting any design problems before prototyping the design. Thus, verification module 165 helps the user to reduce the overall cost and time-to-market of the overall design or system.

Verification module 165 may support and perform a variety of verification and simulation options, as desired. The options may include design-rule checking, functional verification, test-bench generation, static timing analysis, timing simulation, hardware/software simulation, in-system verification, board-level timing analysis, signal integrity analysis and electromagnetic compatibility (EMC), formal netlist verification, and power-consumption estimation, as desired. Note that one may perform other or additional verification techniques as desired and as persons of ordinary skill in the art who have the benefit of the description of the disclosed concepts understand.

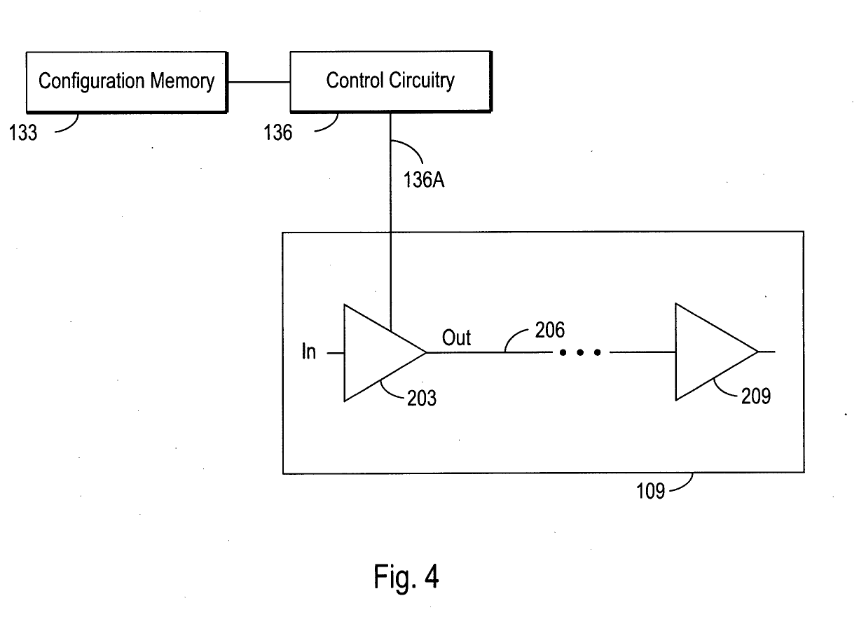

FIG. 4 depicts a conceptual block diagram of circuitry for controlling power consumption in a PLD according to an exemplary embodiment. The circuit arrangement in FIG. 4 includes configuration circuitry 133, control circuitry 136, and programmable interconnect 109. Programmable interconnect 109 includes driver 203, coupling mechanism or channel 206 (e.g., bus, wire, semiconductor material, conductor, metal trace, etc.), and receiver 209.

Control circuitry 136 couples to driver 203 via signal link 136A. Similar to coupling mechanism 206, signal link 136A may include a bus, one or more wires, semiconductor material, conductor, metal trace, etc. Signal link 136A provides a mechanism for communication between control circuitry 136 and driver 203.

Using signal link 136A, control circuitry 136 can provide one or more command or control signals to driver 136. The signals provide a way of adjusting or controlling the “driver strength” of driver 203. Adjusting or controlling the “driver strength” of driver 203 in turn allows the adjustment, control, or optimization of power consumption within driver 203 and, generally, within programmable interconnect 109.

As noted, according to one aspect of the disclosed concepts, during the programming or configuration phase of PLD 103, the CAD software accepts a circuit or function definition from the PLD's user, and program or configure PLD 103 to implement that circuit or function. During this process, the CAD software determines the placement of various PLD resources, as well as the routing of interconnect circuitry 109 to couple the resources.

Depending on factors such as the physical distance or electrical impedance between driver 203 and receiver 209, one might use various levels of “driver strength” for driver 203. For example, if driver 203 physically resides in one corner of PLD 103 and receiver 209 in an opposite physical corner of PLD 103, one might desire to use a relatively high “driver strength” for driver 203 (e.g., higher current-driving capability, shorter rise and fall times, etc.). Conversely, if driver 203 and receiver 209 reside physically close to each other, one might wish to use a relatively low “driver strength” for driver 203.

Under the control of the PLD configuration CAD software (during the configuration phase of PLD 103), configuration CRAM 133 receives and stores information about the “driver strengths” of various drivers 203 in PLD 103. Subsequently, during the user mode or phase of PLD 103 (i.e., when PLD 103 implements the user's circuit or function), control circuitry 136 uses that information to set or adjust the “driver strength” of one or more drivers 203 in PLD 103.

By using the information about each driver 203 (obtained or determined during the configuration phase), one may adjust or control or set the “driver strength” for each driver 203 so as to avoid unnecessary power consumption or dissipation. For example, if a driver 203 needs to provide only 1 mA of current-drive capability, one may use that information (as stored in configuration CRAM 133) to adjust the “driver strength” of driver 203 so that it provides 1 mA or about 1 mA of current-drive capability.

By curbing the “driver strength” of driver 203 to what a particular circuit or topology demands, rather than using a worse-case or overly conservative “driver strength,” one may avoid unnecessary or excessive power consumption or dissipation in driver 203. Considering that a typical PLD includes a relatively high number of drivers, applying this technique to the drivers in the PLD can result in substantial power savings.

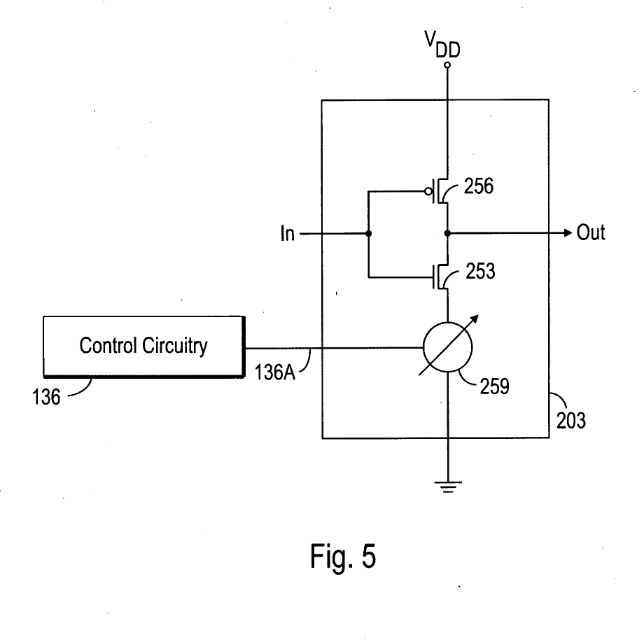

FIG. 5 shows a simplified schematic of a driver circuit 203 according to an exemplary embodiment. Driver 203 couples to, and operates according to one or more control signals received from control circuit 136 via signal link 136A.

Driver 203 includes NMOS transistor 253 and PMOS transistor 256 coupled in an inverter configuration. The source of PMOS transistor 256 couples to a supply voltage, V_{DD}. The source of NMOS transistor 253 couples to supply ground via programmable current source 259. Control circuit 136 couples to programmable current source 259 via signal link 136A.

Using signal link 136A, control circuit 136 programs or controls or adjusts the current sourced or sunk by programmable current source 259. More specifically, control circuit 136 uses signal link 136A to provide one or more control signals to programmable current source 259. The control signals control or adjust or program the amount of current that programmable current source 259 sinks or provides. The sourced or sunk current in turn determines the overall power consumption of driver 203.

Put another way, by using the control signals to program programmable current source 259, control circuit 136 programs or controls or adjusts or optimizes the power consumption of driver 203. By applying this technique to one or more drivers 203 in PLD 103, one may reduce or control or optimize the overall power consumption of PLD 103.

Note that, rather than using complementary metal oxide circuitry, one may use NMOS or PMOS circuitry by making modifications to the circuit arrangement shown, as desired, and as persons of ordinary skill in the art who have the benefit of the description of the disclosed concepts understand. Furthermore, rather than, or in addition to, coupling programmable current source 259 in the supply ground path of driver 203, one may couple programmable current source 259 in the supply (i.e.) path of driver 203, as desired, by making modifications to the circuit arrangement shown, as desired, and as persons of ordinary skill in the art who have the benefit of the description of the disclosed concepts understand.

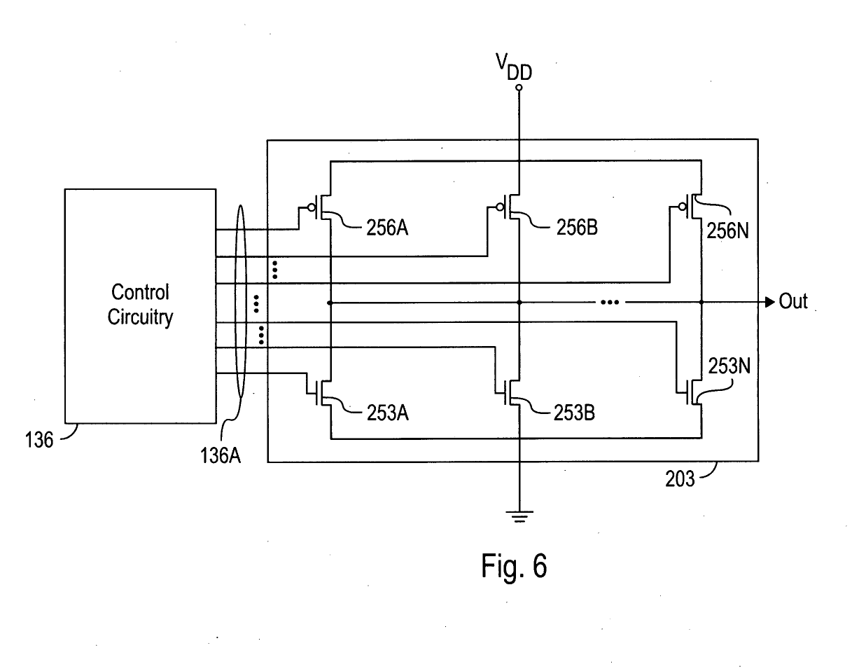

FIG. 6 illustrates a simplified schematic of a driver circuit according to another exemplary embodiment. Similar to FIG. 5, in the circuit arrangement in FIG. 6, driver 203 uses a set of PMOS and NMOS transistors coupled to form a logic inverter. In contrast to the circuit arrangement of FIG. 5, however, the circuit arrangement in FIG. 6 uses parallel transistors to form the logic inverter.

More specifically, driver 203 in FIG. 6 includes a desired number, say, N (where N denotes a positive integer greater than one), NMOS transistors 253A-253N coupled in parallel. Similarly, driver 203 includes PMOS transistors 256A-256N coupled in parallel.

Control circuit 136 couples to driver 203 and, via signal link 136A, provides N signals to control the gate terminals of transistors 253A-253N, and N signals to control the gate terminals of transistors 256A-256N. Put another way, control circuit 136 can selectively turn on or turn off each (or a desired combination of) of transistors 253A-253N and transistors 256A-256N. By doing so, control circuit 136 can program, adjust, control or optimize the effective size of the inverter circuit and, hence, the “driver strength” of driver 203.

One may size transistors 253A-253N and transistors 256A-256N in any desired manner. For example, in one embodiment, one may size the transistors equally (e.g., use the same width-to-length, or W/L, ratio). In another embodiment, one may use set the W/L ratio of transistor 253B twice as large as the W/L ratio of transistor 253A, and so on (in other words, increase the W/L ratios by powers of two). One may apply a similar methodology to the W/L ratios of transistors 256A-256N. As persons of ordinary skill in the art who have the benefit of the description of the disclosed concepts understand, one may use a variety of other methodologies to select sizes for transistors 253A-253N and transistors 256A-256N, as desired, depending on the design and performance specifications for a particular situation.

Note that, rather than using complementary metal oxide circuitry, one may use NMOS or PMOS circuitry by making modifications to the circuit arrangement shown, as desired, and as persons of ordinary skill in the art who have the benefit of the description of the disclosed concepts understand. Furthermore, one may implement control circuit 136 in a variety of ways to provide the gate control signals of transistors 253A-253N and transistors 256A-256N in a variety of ways, as desired, and as persons of ordinary skill in the art who have the benefit of the description of the disclosed concepts understand. The choice of the particular circuitry for control circuit 136 depends on the design and performance specifications for a particular situation.

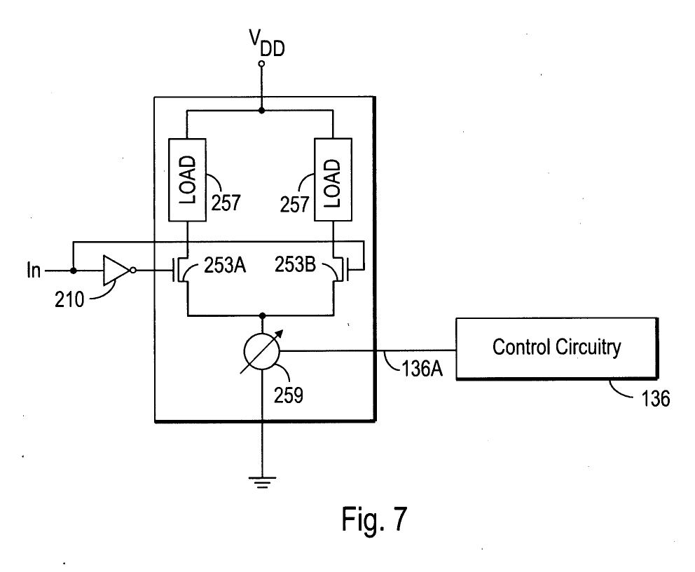

FIG. 7 depicts a simplified schematic of a driver circuit according to an additional exemplary embodiment. The circuit arrangement in FIG. 7 uses a CML configuration, rather than a CMOS configuration (see FIG. 5).

Specifically, driver 203 includes NMOS transistors 253A and 253A, loads 257 (each coupled to a respective one of transistors 253A-253B), programmable current source 259, control circuit 136. Loads 257 couple transistors 253A-253B to supply voltage, V_{DD}. Inverter 210 provides a complement of the input signal, which drives transistor 253A (the true version of the input signal drives transistor 253B).

The sources of NMOS transistors 253A-253B couple to supply ground via programmable current source 259. Control circuit 136 couples to programmable current source 259 via signal link 136A.

Using signal link 136A, control circuit 136 programs or controls or adjusts the current sourced or sunk by programmable current source 259. More specifically, control circuit 136 uses signal link 136A to provide one or more control signals to programmable current source 259. The control signals control or adjust or program the amount of current that programmable current source 259 sinks or provides. The sourced or sunk current in turn determines the overall power consumption of driver 203.

In other words, by using the control signals to program programmable current source 259, control circuit 136 programs or controls or adjusts or optimizes the power consumption of driver 203. By applying this technique to one or more drivers 203 in PLD 103, one may reduce or control or optimize the overall power consumption of PLD 103.

Note that, rather than using NMOS transistors, one may use PMOS transistors by making modifications to the circuit arrangement shown, as desired, and as persons of ordinary skill in the art who have the benefit of the description of the disclosed concepts understand. Furthermore, rather than, or in addition to, coupling programmable current source 259 in the supply ground path of driver 203, one may couple programmable current source 259 in the supply (i.e.) path of driver 203, as desired, by making modifications to the circuit arrangement shown, as desired, and as persons of ordinary skill in the art who have the benefit of the description of the disclosed concepts understand.

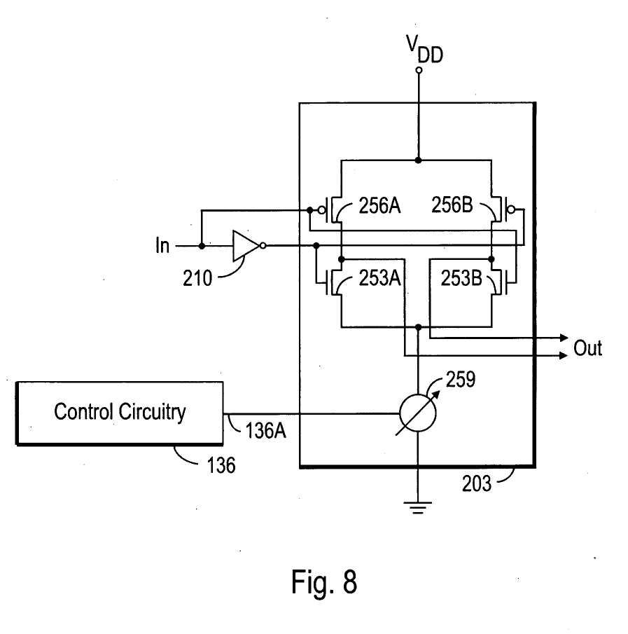

FIG. 8 shows a simplified schematic of a driver circuit according to yet another exemplary embodiment. The circuit arrangement in FIG. 8 employs an H-tree configuration, suitable, for example, LVDS applications.

More specifically, driver 203 in FIG. 8 includes NMOS transistors 253A-253B and PMOS transistors 256A-256B coupled in an “H-configuration.” In addition, the circuit arrangement includes programmable current source 259, control circuit 136.

Inverter 210 provides a complement of the input signal, which drives transistors 253A-253B. The true version of the input signal drives transistors 256A-256B.

Transistors 256A-256B couple to the supply voltage, V_{DD}. The sources of NMOS transistors 253A-253B couple to supply ground via programmable current source 259. Control circuit 136 couples to programmable current source 259 via signal link 136A.

Using signal link 136A, control circuit 136 programs or controls or adjusts the current sourced or sunk by programmable current source 259. More specifically, control circuit 136 uses signal link 136A to provide one or more control signals to programmable current source 259. The control signals control or adjust or program the amount of current that programmable current source 259 sinks or provides. The sourced or sunk current in turn determines the overall power consumption of driver 203.

Put another way, by using the control signals to program programmable current source 259, control circuit 136 programs or controls or adjusts or optimizes the power consumption of driver 203. By applying this technique to one or more drivers 203 in PLD 103, one may reduce or control or optimize the overall power consumption of PLD 103.

Note that, rather than using a CMOS configuration, one may use NMOS transistors or PMOS transistors, by making modifications to the circuit arrangement shown, as desired, and as persons of ordinary skill in the art who have the benefit of the description of the disclosed concepts understand. Furthermore, rather than, or in addition to, coupling programmable current source 259 in the supply ground path of driver 203, one may couple programmable current source 259 in the supply (i.e.) path of driver 203, as desired, by making modifications to the circuit arrangement shown, as desired, and as persons of ordinary skill in the art who have the benefit of the description of the disclosed concepts understand.

Another aspect of the disclosed concepts relates to reducing or controlling or optimizing power consumption in drivers by adjusting or programming or controlling “driver strength” so that the signal transmitted by the driver arrives at the intended receiver without any errors (or with statistically acceptable errors, for example, if one uses error correction codes or similar techniques). In other words, by transmitting a signal from the driver to the receiver via a desired signal path, and monitoring the signal arriving at the receiver, one may determine one or more quality criteria for the arrived signal. For example, one may compare the transmitted and received signals to determine whether they match.

Depending on the results of determining the quality criteria, one may adjust, program, control or optimize the “driver strength” of the corresponding driver (the driver that transmitted the signal). For example, if the signal arrived with an error, one may increase the “driver strength.” Conversely, if the signal arrived without error, one may decrease the “driver strength,” and repeat the signal propagation test.

By repeating this process, one may find a “driver strength” that allows the signal to arrive at the destination (e.g., the corresponding receiver) and meet the desired quality criteria. If desired, one may increase the “driver strength” beyond this threshold value so as to provide a margin of safety or an error margin in order to guard against channel degradation, effects of process, temperature or voltage variations, etc., as persons of ordinary skill in the art who have the benefit of the description of the disclosed concepts understand.

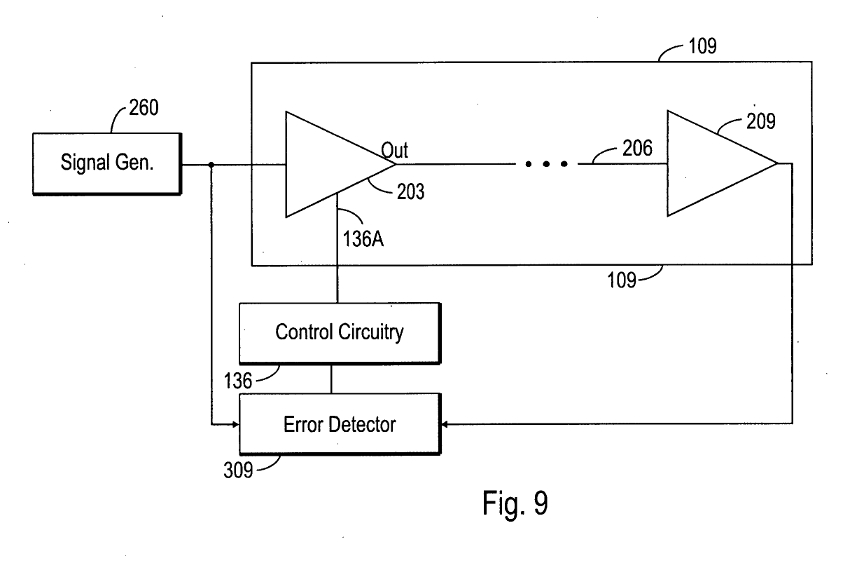

FIG. 9 illustrates a conceptual block diagram of circuitry for controlling power consumption in a PLD according to an exemplary embodiment. The circuit arrangement in FIG. 9 includes signal generator 260, interconnect circuitry 109, error detector 309, and control circuit 136.

Signal generator 260 provides a desired signal to driver 203. Signal generator 260 may use any desired signal, or may use a signal that facilitates detection of a particular type of error, etc. Driver 203 provides its output signal to receiver 209 via coupling mechanism or channel 206.

Receiver 209 provides its output signal to error detector 309. In an exemplary embodiment, error detector 209 may constitute an exclusive-OR (XOR) gate. Rather than an XOR gate, however, one may use other devices or circuits, as persons of ordinary skill in the art who have the benefit of the description of the disclosed concepts understand.

As noted, one may determine the presence of errors in a variety of ways, each with an associated degree of complexity. For example, one use (in order of increasing complexity) one or more parity bits, a checksum, sequence estimation etc. Note that further error evaluation/prediction may occur at FPGA device synthesis phase and/or by using a training sequence (phase) on silicon or be enabled at all times.

Error detector 309 compares the output signal of signal generator 260 and the output signal of receiver 309 to determine whether the received signal meets the quality criterion or criteria (e.g., whether it lacks error), and provides the result at its output. Error detector 309 provides its output signal to control circuit 136. Depending on the results provided by error detector 309, control circuit 136 provides one or more control signals to driver 203 via signal link 136A. The control signal(s) program, adjust, control, or optimize the “driver strength” of driver 203, as described above.

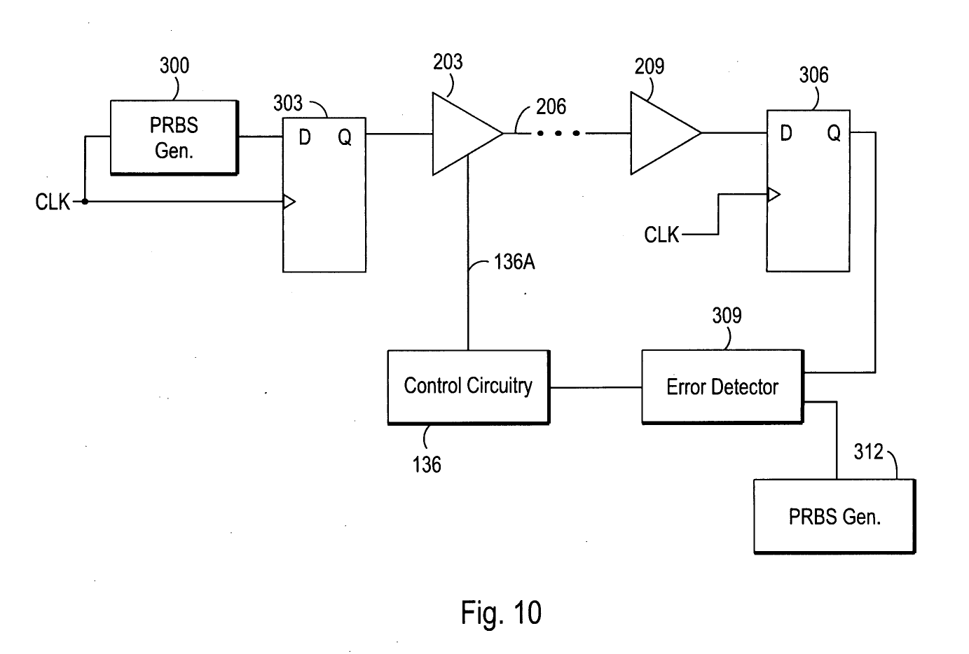

FIG. 10 depicts a conceptual block diagram of circuitry for controlling power consumption in a PLD according to another exemplary embodiment. More specifically, the circuit arrangement in FIG. 10 uses one or more signal quality criteria to affect “driver strength” and, hence, power consumption.

The circuit arrangement in FIG. 10 includes a pseudo-random bit-stream (PRBS) generator 300, flip-flop 303, driver 203, coupled to receiver 209 via coupling mechanism or channel 206, flip-flop 306, error detector 309, PRBS generator 312, and control circuit 136. As the name suggests, PRBS generator 300 and PRBS generator 312 generate a pseudo-random bit-stream or bit-sequence. The design and implementation of suitable PRBS generators falls within the knowledge and level of skill of persons of ordinary skill in the art who have the benefit of the description of the disclosed concepts.

PRBS generator 300 provides its output signal to flip-flop 303. Clock signal CLK clocks the output signal of PRBS generator 300 into flip-flop 303. The output of flip-flop 303 drives the input of driver 203.

Driver 203 provides its output signal to receiver 209 via coupling mechanism 206. Driver 209 provides the received signal to flip-flop 306. Clock signal CLK clocks the information into flip-flop 306. The output of flip-flop 306 drives one input to error detector 309. An output of PRBS generator 312 drives another output of error detector 309. As noted, error detector 309 determines whether the received signal satisfies one or more signal-quality criteria (e.g., whether it contains or lacks errors). Error detector 309 provides the results of that determination to control circuit 136.

Depending on the results provided by error detector 309, control circuit 136 provides one or more control signals to driver 203 via signal link 136A. The control signal(s) program, adjust, control, or optimize the “driver strength” of driver 203, as described above.

Note that, rather than using a single-ended signal path, one may use a differential signal path, as desired (for example, when using low voltage differential signaling (LVDS), or similar signaling schemes), by making appropriate modifications to the circuit arrangement of FIG. 10. Those modifications (e.g., using both the true and complement outputs of flip-flop 303 and a differential-to-single-ended signal converter on the receive side) fall within the knowledge and level of skill of persons of ordinary skill in the art who have the benefit of the description of the disclosed concepts.

One may complement the embodiments described above and in the corresponding figures with software techniques for reducing power consumption of PLDs, as desired, and as noted. For example, one may combine some or all of the circuitry in one or more of the embodiments described in this patent document with techniques for configuring the circuitry within PLD 103 to arrive at a flexible system of controlling or reducing the power consumption of PLDs.

One may apply the disclosed concepts effectively to various ICs that include programmable or configurable logic circuitry, which may be known by other names in the art, as desired, and as persons skilled in the art with the benefit of this disclosure understand. Examples of such circuitry include devices known as complex programmable logic device (CPLD), programmable gate array (PGA), and field programmable gate array (FPGA).

Referring to the figures, persons of ordinary skill in the art will note that the various blocks shown may depict mainly the conceptual functions and signal flow. The actual circuit implementation may or may not contain separately identifiable hardware for the various functional blocks and may or may not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation, as persons of ordinary skill in the art who have the benefit of the description of this disclosure understand. Other modifications and alternative embodiments in addition to those described here will be apparent to persons of ordinary skill in the art who have the benefit of this disclosure. Accordingly, this description teaches those skilled in the art the manner of carrying out the disclosed concepts and are to be construed as illustrative only.

The forms and embodiments shown and described should be taken as the presently preferred or illustrative embodiments. Persons skilled in the art may make various changes in the shape, size and arrangement of parts without departing from the scope of the disclosure described in this document. For example, persons skilled in the art may substitute equivalent elements for the elements illustrated and described here. Moreover, persons skilled in the art who have the benefit of this disclosure may use certain features of the disclosed concepts independently of the use of other features, without departing from the scope of the disclosed concepts.

1. A programmable logic device (PLD), comprising:
a driver circuit;
a configuration circuit that stores driver strength information for the driver circuit; and
a control circuit, wherein the control circuit uses the driver strength information stored in the configuration circuit to control the driver strength of the driver.

2. The programmable logic device (PLD) according to claim 1, wherein the driver strength information comprises current-drive capability information.

3. The programmable logic device (PLD) according to claim 1, wherein the driver comprises a complementary metal oxide semiconductor (CMOS) circuit.

4. The programmable logic device (PLD) according to claim 1, wherein the driver circuit further comprises a programmable current source coupled to the control circuit.

5. The programmable logic device (PLD) according to claim 3, wherein the driver circuit comprises a logic inverter.

6. The programmable logic device (PLD) according to claim 3, wherein the driver circuit comprises a CML circuit.

7. The programmable logic device (PLD) according to claim 3, wherein the driver circuit comprise an H-tree circuit.

8. The programmable logic device (PLD) according to claim 4, wherein the programmable current source controls power consumption of the driver circuit.

9. The programmable logic device (PLD) according to claim 1, wherein the control circuit further receives at least one signal quality criterion, and uses the information to control the driver strength of the driver circuit.

10. A programmable logic device (PLD), comprising:
a driver circuit that communicates a signal;
a receiver circuit that receives the signal, and generates a received signal;
a control circuit that uses at least one quality criterion of the received signal to control a characteristic of the driver circuit.

11. The programmable logic device (PLD) according to claim 10, wherein the driver circuit comprises complementary metal oxide (CMOS) circuitry.

12. The programmable logic device (PLD) according to claim 10, wherein the driver circuit comprises CML circuitry.

13. The programmable logic device (PLD) according to claim 10, wherein the driver circuit comprises H-tree circuitry.

14. The programmable logic device (PLD) according to claim 11, wherein the driver circuitry comprises a logic inverter.

15. The programmable logic device (PLD) according to claim 10, wherein the at least one signal quality criterion comprises whether the received signal includes an error.

16. The programmable logic device (PLD) according to claim 10, further comprising an error detector that compares the signal communicated by the driver circuit and the received signal to generate the at least one signal quality criterion.

17. The programmable logic device (PLD) according to claim 10, wherein the driver receives an output signal of a first pseudo-random bit-stream generator.

18. The programmable logic device (PLD) according to claim 17, further comprising an error detector that compares the received signal and an output signal of a second pseudo-random bit-stream generator to generate the at least one signal quality criterion.

19. The programmable logic device (PLD) according to claim 10, wherein the control circuit further uses information stored in a configuration memory to control the driver strength of the driver circuit.

20. The programmable logic device (PLD) according to claim 19, wherein the stored information is determined by a computer aided design (CAD) software program.

21. A method of controlling power consumption of a programmable logic device (PLD), the method comprising:
generating information about a driver circuit's current-driving capability;
storing the information about the driver circuit's current-driving capability; and
using the information to control the driver circuit's current-driving capability.

22. The method according to claim 21, wherein generating information about a driver circuit's current-driving capability comprises generating the information by using a computer aided design (CAD) software.

23. The method according to claim 21, wherein storing the information about the driver circuit's current-driving capability comprises storing the information in a configuration memory of the programmable logic device (PLD).

24. The method according to claim 21, wherein using the information to control the driver circuit's current-driving capability further comprises controlling a power consumption of the driver circuit by using a programmable current source.

25. The method according to claim 21, wherein using the information to control the driver circuit's current-driving capability further comprises selectively turning on one of a plurality of transistors in the driver circuit.

26. The method according to claim 21, further comprising controlling the driver circuit's current-driving capability based on at least one signal quality criterion.

27. The method according to claim 26, wherein the at least one signal quality criterion comprises determining whether a signal received from the driver circuit lacks error.

28. The method according to claim 27, wherein determining whether a signal received from the driver circuit lacks error further comprises comparing a signal transmitted by the driver circuit with the signal received from the driver circuit.
